(19) United States
(12) Patent Application Publication
(10) Pub. No.: US 2016/0307942 A1
(43) Pub. Date: Oct. 20, 2016

(54) DEEPLY BURIED COLOR FILTER ARRAY (CFA) BY STACKED GRID STRUCTURE

(71) Applicant: Taiwan Semiconductor Manufacturing Co., Ltd., Hsin-Chu (TW)

(72) Inventors: Yun-Wei Cheng, Taipei City (TW); Horng-Huei Tseng, Hsin-Chu City (TW); Chao-Hsiung Wang, Hsin-Chu City (TW); Chun-Hao Chou, Tainan City (TW); Tsung-Han Tsai, Zhunan Township (TW); Kuo-Cheng Lee, Tainan City (TW); Yung-Lung Hsu, Tainan (TW)

(21) Appl. No.: 14/688,094

(22) Filed: Apr. 16, 2015

(51) Int. Cl. H01L 27/146

(52) U.S. Cl. CPC H01L 27/1464; H01L 27/14685; H01L 27/14627; H01L 27/14621; H01L 27/14636

(57) ABSTRACT

The present disclosure relates to a BSI image sensor having a color filter disposed between sidewalls of a metallic grid, and a method of formation. In some embodiments, the BSI image sensor has a pixel sensor located within a semiconductor substrate, and a layer of dielectric material overlying the pixel sensor. A metallic grid is separated from the semiconductor substrate by the layer of dielectric material, and a stacked grid is arranged over the metallic grid. The stacked grid abuts an opening that vertically extends from an upper surface of the stacked grid to a position that is laterally arranged between sidewalls of the metallic grid. A color filter can be arranged within the opening. By having the color filter vertically extend between sidewalls of the metallic grid, a distance between the color filter and the pixel sensor can be made small, thereby improving performance of the BSI image sensor.

### BACKGROUND

Many modern day electronic devices comprise optical imaging devices (e.g., digital cameras) that use image sensors. Image sensors convert optical images to digital data that may represent the images. An image sensor may include an array of pixel sensors and supporting logic. The pixel sensors measure incident radiation (e.g., light), and the supporting logic facilitates readout of the measurements. One type of image sensor commonly used in optical imaging devices is a back-side illumination (BSI) image sensor. BSI image sensor fabrication can be integrated into conventional semiconductor processes for low cost, small size, and high through-put. Further, BSI image sensors have low operating voltage, low power consumption, high quantum efficiency, low read-out noise, and allow random access.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a back-side illumination (BSI) image sensor having a color filter arranged between sidewalls of a metallic grid.

FIG. 2 illustrates a cross-sectional view of some additional embodiments of a BSI image sensor having a color filter arranged between sidewalls of a metallic grid.

FIG. 3 illustrates a three-dimensional view of some additional embodiments of a BSI image sensor having a color filter arranged between sidewalls of a metallic grid.

FIG. 4 illustrates a cross-sectional view of some additional embodiments of a BSI image sensor having a color filter arranged between sidewalls of a metallic grid.

FIG. 5 illustrates a flow diagram of some embodiments of a method of forming a BSI image sensor having a color filter arranged between sidewalls of a metallic grid.

FIGS. 6-11 illustrate some embodiments of cross-sectional views showing a method of forming a BSI image sensor having a color filter arranged between sidewalls of a metallic grid.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Back-side illumination (BSI) image sensors are replacing front-side illumination image sensors in many modern day optical imaging devices due to their higher efficiency in capturing photons. BSI image sensors typically comprise a plurality of pixel sensors and logic circuits arranged in a semiconductor substrate. The plurality of pixel sensors are disposed between a back-side of the semiconductor substrate and the logic circuits. Micro-lenses and color filters are arranged onto the back-side of the integrated chip over the plurality of pixel sensors. The micro-lenses are configured to focus incident radiation (e.g., photons) onto the color filters, which will selectively transmit specified wavelengths of radiation to underlying pixel sensors that generate electrical signals in response to the transmitted radiation.

BSI image sensors typically have a grid structure surrounding the color filters. The grid structure comprises a stacked grid laterally surrounding the color filters, and a metallic grid underlying the stacked grid. During a typical BSI image sensor fabrication process, the metallic grid is fabricated and then covered with a dielectric layer. The stacked grid and color filters are subsequently formed over the dielectric layer, causing lower surfaces of the stacked grid and color filters to vertically overlie an upper surface of the metallic grid. A resulting distance between the color filters and underlying pixel sensors depends on a height of the metallic grid. It has been appreciated that by reducing the distance between the color filters and the underlying pixel sensors, cross-talk between adjacent color filters can be decreased, while enhancing optical performance of associated pixel sensors.

Accordingly, the present disclosure relates to a back-side illumination (BSI) image sensor that has a color filter that is vertically disposed between sidewalls of a metallic grid, and a method of formation. In some embodiments, the BSI image sensor comprises a pixel sensor located within a semiconductor substrate, and a layer of dielectric material disposed over the pixel sensor. A metallic grid, comprising a metal framework, is separated from the semiconductor substrate by the layer of dielectric material. A stacked grid is arranged over the metallic grid. The stacked grid abuts an opening that vertically extends from an upper surface of the stacked grid to a position that is laterally arranged between sidewalls of the metallic grid. A color filter can be arranged within the opening. By having the color filter vertically extend between sidewalls of the metallic grid, a distance between the color filter and the pixel sensor can be made relatively small, thereby decreasing cross-talk and improving optical performance of the resulting BSI image sensor.

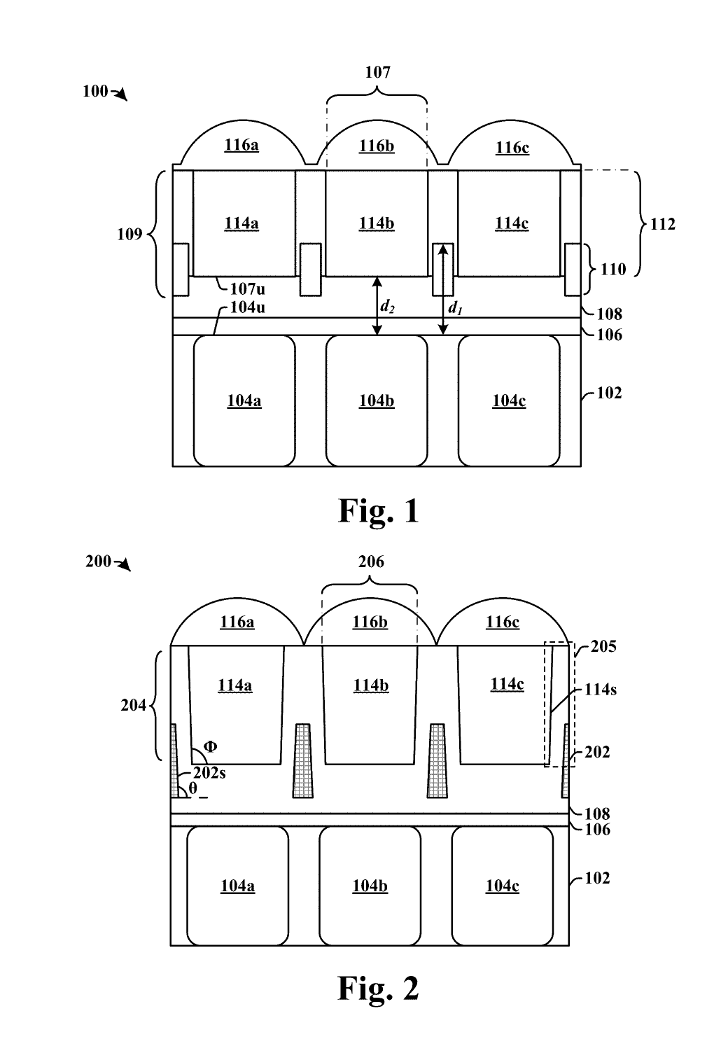

FIG. 1 illustrates a cross-sectional view of some embodiments of a back-side illumination (BSI) image sensor 100 having a color filter arranged between sidewalls of a metallic grid.

The BSI image sensor 100 comprises a semiconductor substrate 102 having a plurality of pixel sensors 104 configured to convert radiation (e.g., photons) into an electric signal. In some embodiments, the plurality of pixel sensors 104 may comprise photodiodes. In such embodiments, the photodiodes may comprise a first region within the semiconductor substrate 102 having a first doping type (e.g., n-type doping) and an overlying second region within the semiconductor substrate 102 having a second doping type (e.g., p-type doping) that is different than the first doping type. In some embodiments, the plurality of pixel sensors 104 may be arranged within the semiconductor substrate 102 in an array comprising in rows and/or columns.

A passivation layer 106 may be arranged over the semiconductor substrate 102. In some embodiments, the passivation layer 106 may comprise an anti-reflective coating (ARC), such as a bottom resist anti-reflective coating (BARC), for example. In some embodiments, the passivation layer 108 may comprise an organic polymer or a metallic oxide.

A layer of dielectric material 108 is arranged over the passivation layer 106. The layer of dielectric material 108 vertically separates the semiconductor substrate 102 from an overlying metallic grid 110 comprising a metal framework. In some embodiments, the layer of dielectric material 108 may abut a lower surface of the metallic grid 110. In some embodiments, layer of dielectric material 108 may further abut one or more sidewalls of the metallic grid 110 and/or an upper surface of the metallic grid 110. The metallic grid 110 extends above an upper surface of the semiconductor substrate 102 by a first distance d₁.

A stacked grid 112 is disposed over the metallic grid 110. The stacked grid 112 may abut an upper surface the metallic grid 110. In some embodiments, the stacked grid 112 may further abut one or more sidewalls of the metallic grid 110. In such embodiments, the stacked grid 112 vertically overlies the metallic grid 110 so that a lower surface of the stacked grid 112 underlies an upper surface of the metallic grid 110. In some embodiments, the stacked grid 112 may comprise a same material as the layer of dielectric material 108. For example, the stacked grid 112 and the layer of dielectric material 108 may comprise silicon-dioxide (SiO₂). In such embodiments, the stacked grid 112 comprises protrusions extending outward from the layer of dielectric material 108 and abutting sidewalls of the metallic grid 110. In other embodiments, the stacked grid 112 may comprise one or more materials different than the layer of dielectric material 108.

The stacked grid 112 and the metallic grid 110 collectively provide for a grid structure 109 comprising a framework that defines a plurality of openings 107. The plurality of openings 107 are located over the underlying pixel sensors 104 and extend from an upper surface of the stacked grid 112 to a position that is laterally arranged between sidewalls of the metallic grid 110. The metallic grid 110 vertically extends from a position underlying the plurality of openings 107 to a location adjacent to the plurality of openings 107. In some embodiments, a lower surface of the metallic grid 110 is vertically underlies a lower surface 107u of the plurality of openings 107. The lower surface 107u of the plurality of openings 107 extends above an upper surface of the semiconductor substrate 102 by an second distance d₂, wherein a ratio of the second distance d₂ to the first distance d₁ is in a range of between approximately 0.1 and approximately 5 (i.e., 0.1<d₂/d₁<5).

A plurality of color filters 114 are disposed within the plurality of openings 107, so that the grid structure 109 extends around and between the plurality of color filters 114. The color filters 114 are respectively configured to transmit specific wavelengths of radiation. For example, a first color filter 114a (e.g., a red color filter) may transmit light having wavelengths within a first range, while a second color filter 114b may transmit light having wavelengths within a second range different than the first range.

A plurality of micro-lenses 116 are arranged over the plurality of color filters 114. Respective micro-lenses 116 are aligned laterally with the color filters 114 and overlie the pixel sensors 104. The micro-lenses 116 are configured to focus incident radiation (e.g., light) towards the pixel sensors 104. In some embodiments, the plurality of micro-lenses 116 have a substantially flat bottom surface abutting the color filters 114. Furthermore, the plurality of micro-lenses 116 may respectively comprise a curved upper surface. In various embodiments, the micro-lenses 116 may have a curvature configured to focus the radiation onto a center of an underlying pixel sensor 104.

By positioning the color filters 114 laterally between sidewalls of the metallic grid 110, the distance d between a lower surface of the color filters 114 and an upper surface 104u of an underlying pixel sensor 104 is reduced, thereby reducing cross-talk and improving optical performance of the BSI image sensor 100.

FIG. 2 illustrates a cross-sectional view of some additional embodiments of a BSI image sensor 200 having a color filter arranged between sidewalls of a metallic grid.

The BSI image sensor 200 comprises a metallic grid 202 disposed within a layer of dielectric material 108 arranged over a semiconductor substrate 102 having a plurality of pixel sensors 104. The metallic grid 202 vertically extends from a first position underlying the color filters 114 to a second position between adjacent ones of the color filters 114. In various embodiments, the metallic grid 202 may be a metal, such as, for example, tungsten, copper, or aluminum copper. In some embodiments, the metallic grid 202 may have tapered sidewalls 202s that have an angle θ that is greater than 90 degrees. The tapered sidewalls 202s cause a width of the metallic grid 202 to decrease as a function of height.

A stacked grid 204 is arranged over the metallic grid 202. In some embodiments, the stacked grid 204 may comprise a plurality of protrusions 205 of the layer of dielectric material 108 that extend outward from the layer of dielectric material 108. In such embodiments, the plurality of protrusions 205 abut the sidewalls 202s of the metallic grid 202 and extends to a position overlying the metallic grid 202. The plurality of protrusions 205 define openings 206 that vertically extend from an upper surface of the layer of dielectric material 108 to a position that is laterally arranged between sidewalls of the metallic grid 202.

Color filters 114 are arranged over the pixel sensors 104 within openings vertically extending between sidewalls of the metallic grid 202 and the stacked grid 204. In some embodiments, the color filters 114 may have tapered sidewalls 114s that have an angle φ that is less than 90 degrees (i.e., so that the slope of tapered sidewalls 202s has an opposite sign as the slope of tapered sidewalls 114s). The tapered sidewalls 114s cause a width of the color filters 114 to increase as a function of height.

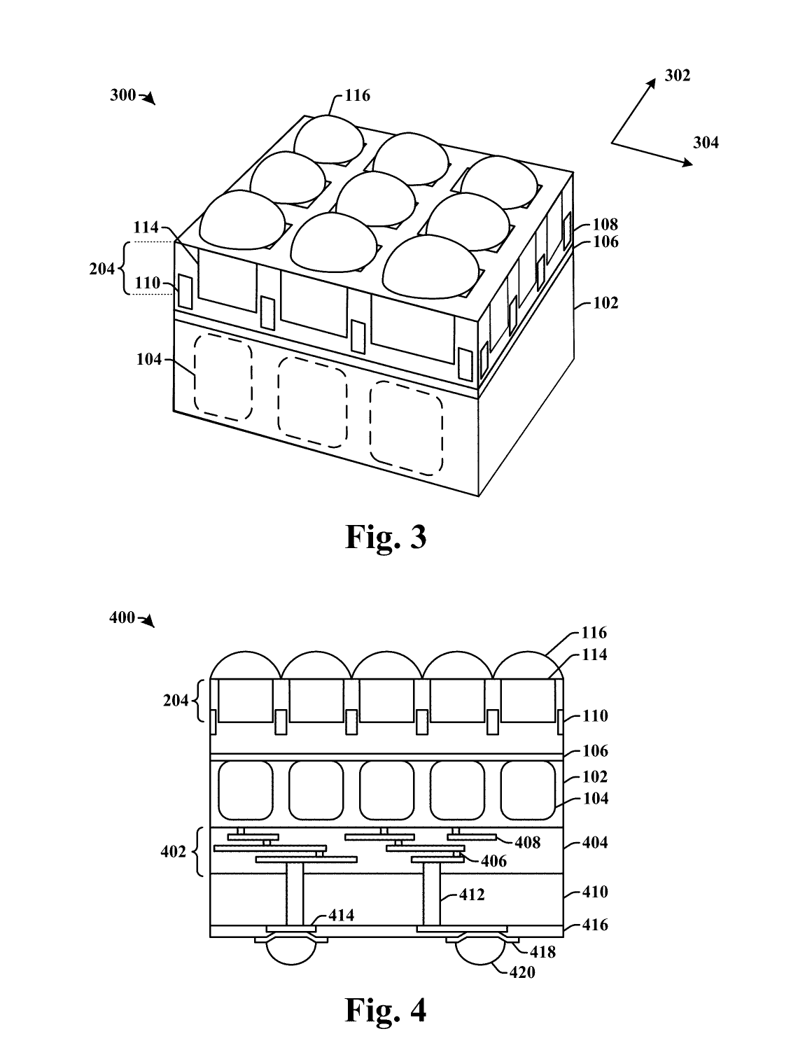

FIG. 3 illustrates a three-dimensional view of some embodiments of an integrated chip 300 comprising a plurality of BSI image sensors.

The integrated chip 300 comprises a plurality of micro-lenses 116 disposed in an array. Within the array, the plurality of micro-lenses 116 are aligned in a first direction 302 and in a second direction 304, which is perpendicular to the first direction 302. The plurality of micro-lenses 116 overlie an array of color filters 114 disposed within a grid structure comprising a metallic grid 110 and a stacked grid 204. The grid structure comprises a first plurality of lines extending between adjacent color filters 114 in the first direction 302 and a second plurality of lines intersecting the first plurality of lines and extending between adjacent color filters 114 in the second direction 304.

FIG. 4 illustrates a cross-sectional view of some additional embodiments of an integrated chip 400 comprising a BSI image sensor having a color filter arranged between sidewalls of a metallic grid.

The integrated chip 400 comprises a dielectric layer 108 arranged above a semiconductor substrate 102 and a back-end-of-the-line (BEOL) metal stack 402 arranged below the semiconductor substrate 102. The BEOL metal stack 402 includes a plurality of metal interconnect layers, 406 and 408, surrounded by one or more interlayer dielectric (ILD) layers 404. In some embodiments, the one or more metal interconnect layers may comprise metal via layers 406 and metal wire layers 408. In various embodiments, the ILD layer 404 may be, for example, a low κ dielectric layer (i.e., a dielectric with a dielectric constant less than about 3.9), an ultra low-k dielectric layer, or an oxide (e.g., silicon oxide). The plurality of metal interconnect layers may comprise a metal, such as copper, tungsten, or aluminum.

A carrier substrate 410 is arranged below the BEOL metal stack 402. A plurality of through-substrate-vias (TSVs) 412 vertically extend through the carrier substrate 410. The plurality of TSVs 412 extend from the plurality of metal interconnect layers to a redistribution layer 414 located within a protection layer 416. The redistribution layer 414 provides for an electrical connection between the plurality of TSV 412 and a plurality of solder balls 420. In some embodiments, the redistribution layer 414 may comprise a conductive metal such as aluminum, for example.

In some embodiments, an under bump metallurgy (UBM) layer 418 may be disposed between the redistribution layer 414 and the plurality of solder balls 420. The UBM layer 418 may comprise a plurality of different metal layers, such as an adhesion layer, a diffusion barrier layer, a solderable layer, and an oxidation barrier layer. In various embodiments, the UBM layer 418 may comprise one or more of chromium (Cr), copper (Cu), titanium (Ti), nickel (Ni), etc.

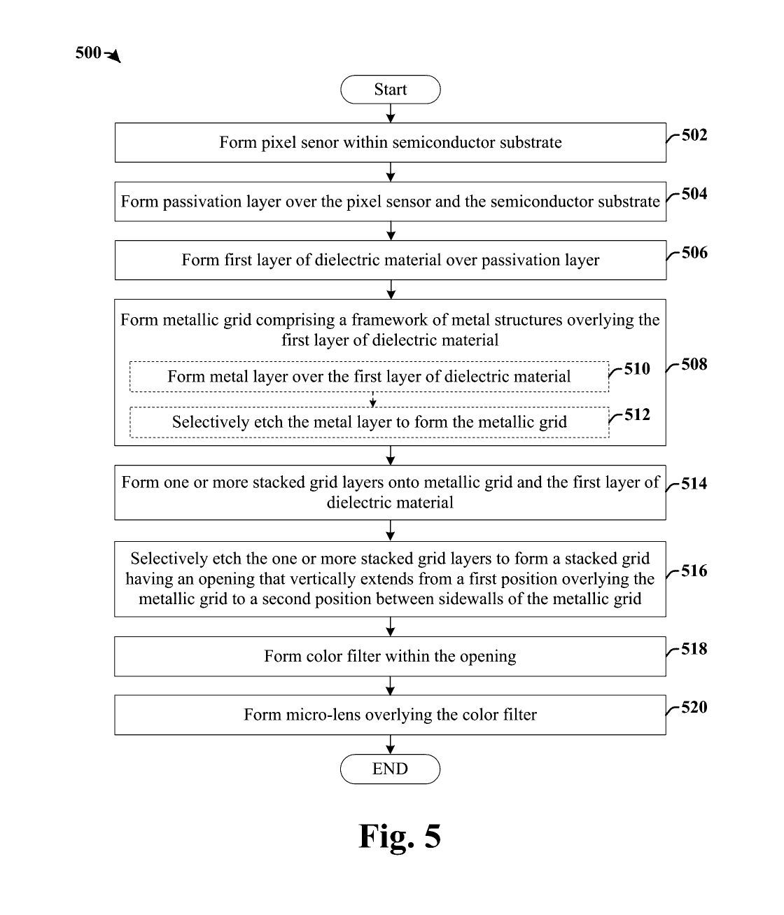

FIG. 5 illustrates a flow diagram of some embodiments of a method 500 of forming a BSI image sensor having a color filter arranged between sidewalls of a metallic grid.

While the disclosed method 500 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 502, a pixel senor is formed within a semiconductor substrate.

At 504, a passivation layer is formed over the pixel sensor and the semiconductor substrate.

At 506 a first layer of dielectric material (e.g., SiO₂) is formed over the passivation layer.

At 508, a metallic grid comprising a framework of metal structures is formed over the first layer of dielectric material. In some embodiments, the metallic grid is separated from the semiconductor substrate by the passivation layer and/or the layer of dielectric material. The metallic grid is formed to have an opening that overlies the pixel sensor. In some embodiments, the metallic grid is formed according to acts 510-512.

At 510, a metal layer is formed over the first layer of dielectric material.

At 512, the metal layer is selectively etched to form the metallic grid. The metallic grid comprises a framework of metal disposed onto the first layer of dielectric material, which defines the opening.

At 514, one or more stacked grid layers are formed onto the metallic grid and the first layer of dielectric material. In some embodiments the one or more stacked grid layer may comprise a second layer of dielectric material (e.g., SiO₂).

At 516, the one or more stacked grid layers are selectively etched to form a stacked grid defining an opening that extends from a first position overlying the metallic grid to a second position between sidewalls of the metallic grid.

At 518, a color filter is formed within the opening. The color filter fills the opening, so as to vertically extend from the first position overlying the metallic grid to the second position between sidewalls of the metallic grid.

At 520, a micro-lens is formed over the color filter.

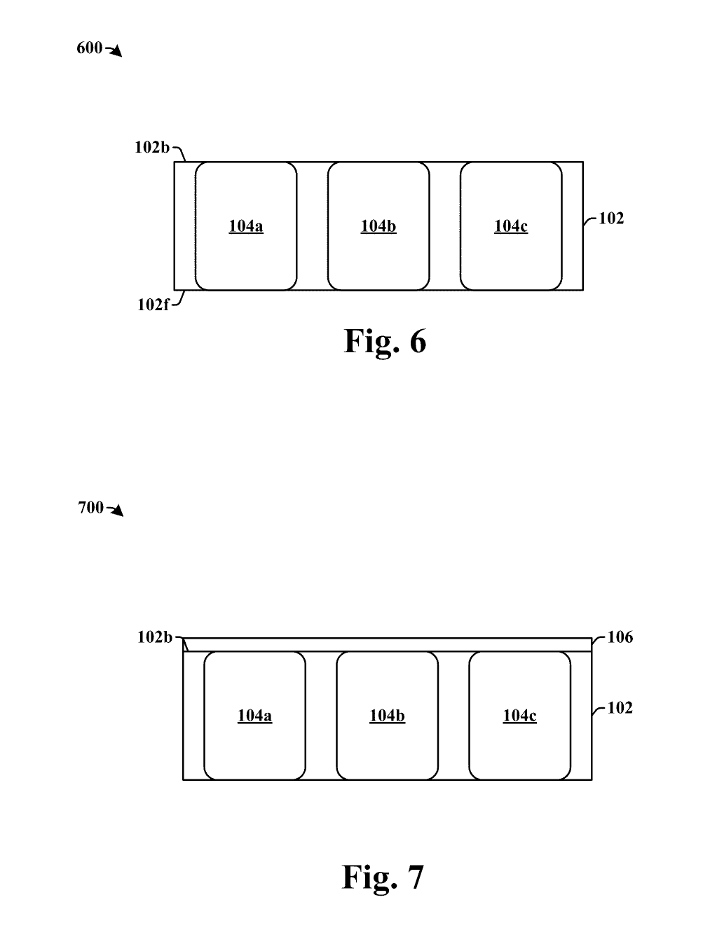

FIGS. 6-11 illustrate some embodiments of cross-sectional views showing a method 500 of forming a BSI image sensor. Although FIGS. 6-11 are described in relation to method 500, it will be appreciated that the structures disclosed in FIGS. 6-11 are not limited to such a method, but instead may stand alone as structures independent of the method.

FIG. 6 illustrates some embodiments of a cross-sectional view 600 of an integrated chip corresponding to act 502.

As shown in cross-sectional view 600, a plurality of pixel sensors 104 are formed within a semiconductor substrate 102. The semiconductor substrate 102 may comprise any type of semiconductor body (e.g., silicon/CMOS bulk, SiGe, SOI, etc.) such as a semiconductor wafer or one or more die on a wafer, as well as any other type of semiconductor and/or epitaxial layers formed thereon and/or otherwise associated therewith. In some embodiments, the plurality of pixel sensors 104 may comprise photodiodes. In such embodiments, the photodiode may be formed by selectively implanting the semiconductor substrate 102 with a first implantation process to form a first region having a first doping type, and a second subsequent implantation process to form an abutting second region having a second doping type different than the first doping type. In some embodiments, the semiconductor substrate 102 may be selectively implanted according to a patterned masking layer (not shown) comprising photoresist.

In some embodiments, the plurality of pixel sensors 104 may be formed within a back-side 102b of the semiconductor substrate 102. In such embodiments, the back-side 102b of the semiconductor substrate 102 opposes a front-side 102f of the semiconductor substrate 102 comprising a plurality of transistor devices (not shown). In some embodiments, a BEOL metal stack (not shown) is arranged onto the front-side 102f of the semiconductor substrate 102. The BEOL metal stack comprises a plurality of metal interconnect layers disposed within one or more inter-level dielectric (ILD) layers and electrically coupled to the plurality of transistor devices.

FIG. 7 illustrates some embodiments of a cross-sectional view 700 of an integrated chip corresponding to act 504.

As shown in cross-sectional view 700, a passivation layer 106 is formed onto the back-side 102b of the semiconductor substrate 102 at a position overlying the plurality of pixel sensors 104. In some embodiments, the passivation layer 106 may comprise an anti-reflective coating (ARC) layer. In some embodiments, the passivation layer 106 may be deposited by way of a spin coating process. In other embodiments, the passivation layer 106 may be deposited by way of a vapor deposition process (e.g., chemical vapor deposition (CVD), physical vapor deposition (PVD), plasma enhanced chemical vapor deposition (PECVD), etc.). After deposition of the passivation layer 106 a high temperature bake may be performed, in some embodiments.

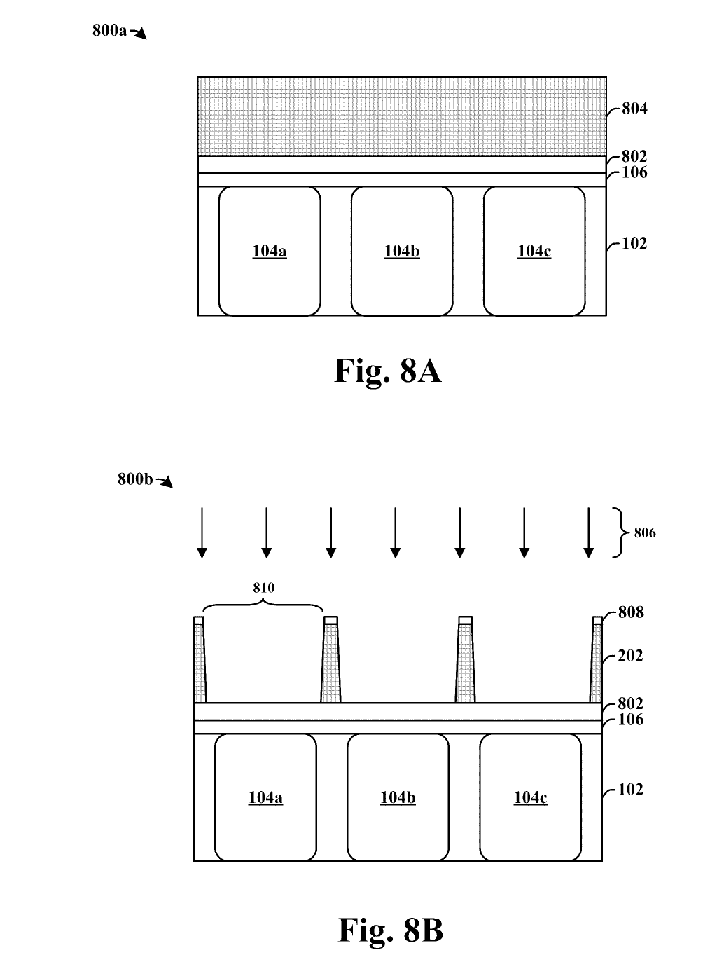

FIGS. 8A-8B illustrates some embodiments of cross-sectional views, 800a and 800b, of an integrated chip corresponding to act 506-508.

As shown in cross-sectional view 800a, a first layer of dielectric material 802 is formed over the passivation layer 106 (corresponding to act 508), and a metal layer 804 is subsequently formed over the first layer of dielectric material 802 (corresponding to act 510). The first layer of dielectric material 802 may be formed using a deposition process. The metal layer 804 may be formed using a deposition process and/or a plating process (e.g., electroplating, electro-less plating, etc.). In various embodiments, the metal layer 804 may comprise tungsten, copper, or aluminum copper, for example.

As shown in cross-sectional view 800b, a first etching process is performed to pattern the metal layer 804 to define a metallic grid 202 (corresponding to act 512) having metal structures that surround openings 810 overlying the pixel sensors 104. The first etching process may be performed by selectively exposing the metal layer 804 to a first etchant 806 according to a first masking layer 808. In some embodiments, the first etchant 806 may comprise a dry etchant. In some embodiments, the dry etchant may have an etching chemistry comprising one or more of oxygen (0₂), nitrogen (N₂), hydrogen (H₂), argon (Ar), and/or a fluorine species (e.g., CF₄, CHF₃, C₄F₈, etc.). In other embodiments, the first etchant 806 may comprise a wet etchant comprising a buffered hydroflouric acid (BHF).

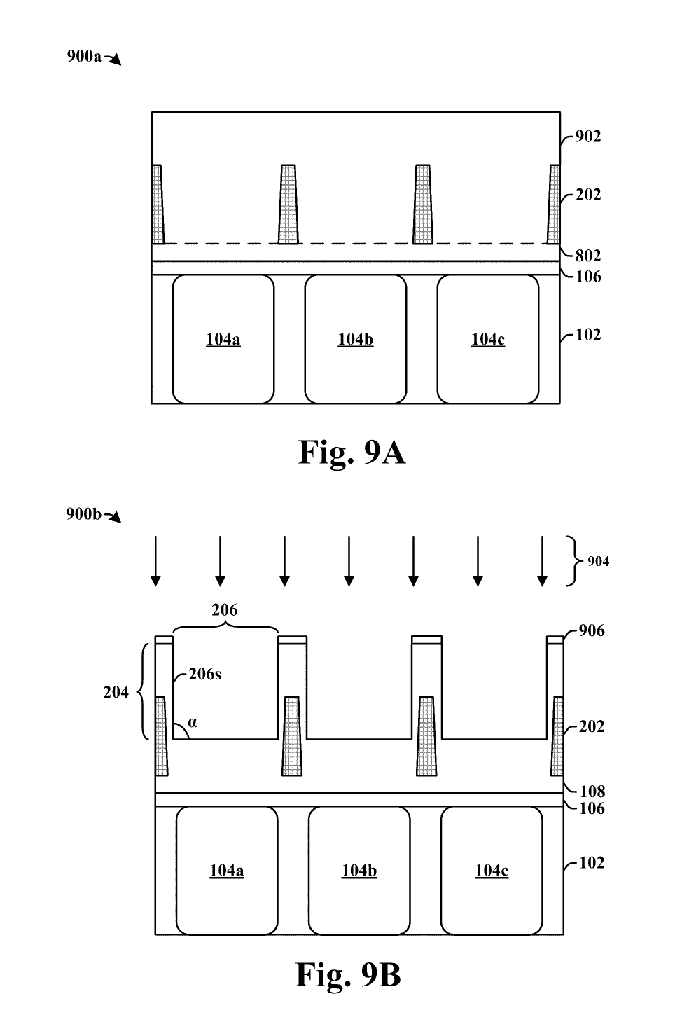

FIGS. 9A-9B illustrate some embodiments of cross-sectional views, 900a and 900b, of an integrated chip corresponding to acts 514-516.

As shown in cross-sectional view 900a, one or more stacked grid layers 902 are formed over the metallic grid 202 (corresponding to act 516). In some embodiments, the one or more stacked grid layers 902 may comprise a second layer of dielectric material (e.g., silicon-dioxide (SiO₂)) formed onto an upper surface of the first layer of dielectric material 802 (between sidewalls of the metallic grid). In such embodiments, the second layer of dielectric material may be formed to a thickness that causes the one or more stacked grid layers 902 to extend over the metallic grid 202.

As shown in cross-sectional view 900b, a second etching process is performed to form openings 206 in the one or more stacked grid layers 902 that define the stacked grid 204 (corresponding to act 518). The openings 206 overlie the plurality of pixel sensors 104 and vertically extend to a position between sidewalls of the metallic grid 202 so that the stacked grid 204 vertically overlies the metallic grid 202. In some embodiments (not shown), the openings 206 may have tapered sidewalls 206s that have an angle a that is greater than 90 degrees.

The second etching process may be performed by selectively exposing the one or more stacked grid layers 902 to a second etchant 904 according to a second masking layer 906. In some embodiments, the second etchant 904 may comprise a dry etchant. In some embodiments, the dry etchant may have an etching chemistry comprising one or more of oxygen (O₂), nitrogen (N₂), hydrogen (H₂), argon (Ar), and/or a fluorine species (e.g., CF₄, CHF₃, C₄F₈, etc.). In other embodiments, the second etchant 904 may comprise a wet etchant comprising a buffered hydroflouric acid (BHF).

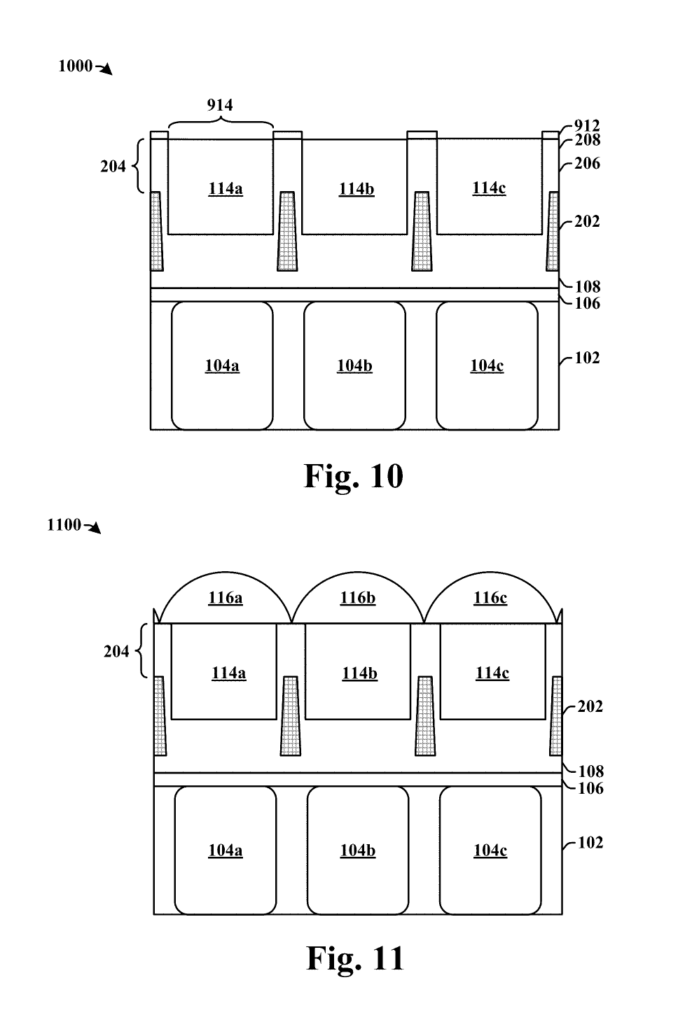

FIG. 10 illustrates some embodiments of a cross-sectional view 1000 of an integrated chip corresponding to act 518.

As shown in cross-sectional view 1000, a plurality of color filters 114 are formed to fill the openings 206. In some embodiments, the plurality of color filters 114 may be formed by forming a color filter layer and patterning the color filter layer. The color filter layer is formed so as to fill exposed regions of the openings 206. The color filter layer is formed of a material that allows for the transmission of radiation (e.g., light) having a specific range of wavelength, while blocking light of wavelengths outside of the specified range. Further, in some embodiments, the color filter layer is planarized subsequent to formation. The patterning may be performed by forming a photoresist layer with a pattern over the color filter layer, applying an etchant to the color filter layer according to the pattern of the photoresist layer, and removing the pattern photoresist layer.

FIG. 11 illustrates some embodiments of a cross-sectional view 1100 of an integrated chip corresponding to act 520.

As shown in cross-sectional view 1100, a plurality of micro-lenses 116 are formed over the plurality of color filters 114. In some embodiments, the micro-lenses 116 may be formed by depositing a micro-lens material above the plurality of color filters 114 (e.g., by a spin-on method or a deposition process). A micro-lens template (not shown) having a curved upper surface is patterned above the micro-lens material. In some embodiments, the micro-lens template may comprise a photoresist material exposed using a distributing exposing light dose (e.g., for a negative photoresist more light is exposed at a bottom of the curvature and less light is exposed at a top of the curvature), developed and baked to form a rounding shape. The micro-lenses 116 are then formed by selectively etching the micro-lens material according to the micro-lens template.

Therefore, the present disclosure relates to a back-side illumination (BSI) sensor that has a color filter that is vertically disposed between sidewalls of a metallic grid, so that a distance between the color filter and an underlying pixel sensor is relatively small, and a method of formation.

In some embodiments, the present disclosure relates to a back-side illuminated (BSI) image sensor. The BSI image sensor comprises a pixel sensor located within a semiconductor substrate, and a layer of dielectric material overlying the pixel sensor. The BSI image sensor further comprises a metallic grid comprising a metal framework separated from the semiconductor substrate by the layer of dielectric material, and a stacked grid arranged over the metallic grid and abutting an opening that vertically extends from an upper surface of the stacked grid to a position that is laterally arranged between sidewalls of the metallic grid.

In other embodiments, the present disclosure relates to a BSI image sensor. The BSI image sensor comprises a plurality of pixel sensors located within a first side of a semiconductor substrate. The BSI image sensor comprises a metallic grid comprising a framework of metal structures disposed over the semiconductor substrate, and a layer of dielectric material disposed between the semiconductor substrate and the metallic grid and comprising a plurality of protrusions that abut sidewalls and an upper surface of the metallic grid. The plurality of protrusions define openings that vertically extend from an upper surface of the layer of dielectric material to a position that is laterally arranged between sidewalls of the metallic grid.

In yet other embodiments, the present disclosure relates to a method of forming a BSI image sensor. The method comprises forming a pixel senor within a semiconductor substrate. The method further comprises forming a metallic grid comprising a framework of metal structures laterally surrounded by a layer of dielectric material overlying the pixel sensor, and forming one or more stacked grid layers over the metallic grid and the layer of dielectric material. The method further comprises selectively etching the one or more stacked grid layers to form a stacked grid defining an opening that vertically extends between sidewalls of the metallic grid.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A back-side illuminated (BSI) image sensor, comprising:
a pixel sensor located within a semiconductor substrate;
a layer of dielectric material overlying the pixel sensor;
a metallic grid comprising a metal framework separated from the semiconductor substrate by the layer of dielectric material; and
a stacked grid arranged over the metallic grid and abutting an opening that vertically extends from an upper surface of the stacked grid to a position that is laterally arranged between sidewalls of the metallic grid.

2. The BSI image sensor of claim 1, further comprising:
a color filter arranged within the opening and having a lower surface that is vertically offset from a lower surface of the metallic grid.

3. The BSI image sensor of claim 2, further comprising:
a micro-lens having a substantially flat lower surface abutting the color filter and a curved upper surface.

4. The BSI image sensor of claim 1, further comprising:
a plurality of metal interconnect layers disposed within one or more inter-level dielectric (ILD) layers arranged on an opposite side of the semiconductor substrate as the layer of dielectric material.

5. The BSI image sensor of claim 1, wherein the stacked grid and the layer of dielectric material comprise silicon-dioxide (SiO₂).

6. The BSI image sensor of claim 5, wherein the stacked grid abuts a sidewall of the metallic grid.

7. The BSI image sensor of claim 1, wherein the metallic grid has a tapered sidewall that causes a width of the metallic grid to decrease as a height of the metallic grid increases.

8. The BSI image sensor of claim 1, wherein the metallic grid is laterally separated from the opening by the stacked grid.

9. The BSI image sensor of claim 1, wherein an upper surface of the metallic grid is separated from the semiconductor substrate by a first distance and a lower surface of the opening is separated from the semiconductor substrate by a second distance; and
wherein a ratio of the second distance to the first distance is in a range of between approximately 0.1 and approximately 5.

10. A BSI image sensor, comprising:
a plurality of pixel sensors located within a first side of a semiconductor substrate;
a metallic grid comprising a framework of metal structures disposed over the semiconductor substrate;
a layer of dielectric material disposed between the semiconductor substrate and the metallic grid and comprising a plurality of protrusions that abut sidewalls and an upper surface of the metallic grid; and
wherein the plurality of protrusions define openings that vertically extend from an upper surface of the layer of dielectric material to a position that is laterally arranged between sidewalls of the metallic grid.

11. The BSI image sensor of claim 10, further comprising:
a plurality of metal interconnect layers disposed within one or more inter-level dielectric (ILD) layers arranged on a second side of the semiconductor substrate opposing the first side of the semiconductor substrate.

12. The BSI image sensor of claim 11, further comprising:
a plurality of color filters overlying the layer of dielectric material and arranged between the sidewalls of the metallic grid, wherein the plurality of color filters have lower surfaces that are vertically offset from a lower surface of the metallic grid; and
a plurality of micro-lenses arranged over the plurality of color filters.

13. The BSI image sensor of claim 11, wherein the metallic grid has a tapered sidewall that causes a width of the metallic grid to decrease as a height of the metallic grid increases.

14. The BSI image sensor of claim 11, wherein the layer of dielectric material comprises silicon-dioxide (SiO₂).

15. The BSI image sensor of claim 11, further comprising:
a passivation layer abutting the first side of the semiconductor substrate and the layer of dielectric material.

16-20. (canceled)

21. An integrated chip, comprising:
a plurality of image sensors located within a semiconductor substrate;
a first layer of dielectric material arranged over the semiconductor substrate;
a metallic grid arranged between adjacent ones of the plurality of image sensors, and having a lower surface facing the first layer of dielectric material and an upper surface and sidewalls covered by a second layer of dielectric material;
a plurality of recesses within an upper surface of the second layer of dielectric material and vertically extending from the upper surface to a position that is laterally arranged between sidewalls of the metallic grid; and
a plurality of metal interconnect layers disposed within one or more inter-level dielectric (ILD) layers that are separated from the first layer of dielectric material by the semiconductor substrate.

22. The integrated chip of claim 21, further comprising:
a passivation layer arranged between the semiconductor substrate and the first layer of dielectric material.

23. The integrated chip of claim 21, wherein the second layer of dielectric material has a lower surface that is co-planar with a lower surface of the metallic grid.

24. The integrated chip of claim 21, a plurality of color filters arranged within the plurality of recesses and having lower surfaces that are vertically offset from a lower surface of the metallic grid, and an upper surface that is co-planar with an upper surface of the second layer of dielectric material.

25. The integrated chip of claim 21, wherein the second layer of dielectric material has a greater thickness above the upper surface of the metallic grid than along sidewalls of the metallic grid.
